(19) United States
(12) Patent Application Publication
(10) Pub. No.: US 2022/0028726 A1
(43) Pub. Date: Jan. 27, 2022

(54) METHOD FOR FORMING A CAPACITIVE ISOLATION TRENCH AND SUBSTRATE COMPRISING SUCH A TRENCH

(71) Applicant: STMicroelectronics (Crolles 2) SAS, Crolles (FR)

(72) Inventors: Denis MONNIER, Saint Ismier (FR); Francois LEVERD, Saint Ismier (FR)

(73) Assignee: STMicroelectronics (Crolles 2) SAS, Crolles (FR)

(21) Appl. No.: 17/376,732

(22) Filed: Jul. 15, 2021

(51) Int. Cl. H01L 21/762; H01L 27/146; H01L 21/02

(52) U.S. Cl. CPC H01L 21/76224; H01L 21/763; H01L 21/02271; H01L 27/1463

(57) ABSTRACT

A method for forming a capacitive isolation trench in a semiconductor substrate includes digging a trench from a main surface of the substrate, the trench including an upper portion gradually widening from a neck in the direction of a lower portion of the trench. A coating of a first electrically isolating material is formed on the walls of the trench. A first semiconductor material is deposited on the coating, with the deposition being interrupted so as to leave a free space between the walls of the trench, the free space having an opening at the neck. A second electrically isolating material is deposited in the trench, with the deposition resulting in the formation of a plug closing the opening to form a closed cavity. The plug is etched so as to open the cavity, and a second semiconductor material or a metal is deposited so as to fill the cavity.

### CROSS-REFERENCE TO RELATED APPLICATION

This application claims the priority benefit of French patent application number FR2007905, filed on 27 Jul. 2020, which is hereby incorporated by reference to the maximum extent allowable by law.

### BACKGROUND

### Technical Field

The present disclosure relates to a method for forming a capacitive isolation trench in a semiconductor substrate. This method can in particular be implemented during the manufacture of semiconductor substrates for image sensors, said capacitive isolation trench being intended to electrically isolate two adjacent pixels.

### Description of the Related Art

Capacitive Isolation Trenches, known by the acronym CDTI (from the term “Capacitive Deep Trench Isolation”) are used for rear-illuminated image sensors. Such sensors are formed from a semiconductor substrate, in particular a silicon substrate, wherein a plurality of photodiodes each defining a pixel of the sensor are arranged. Capacitive isolation trenches are arranged vertically in the substrate, that is to say, perpendicular to the main surface of the substrate which is considered horizontal, in order to electrically isolate the pixels from each other.

Unlike conventional isolation trenches, designated by the acronym DTI (from the term “Deep Trench Isolation”), which are formed from an electrically isolating material such as silicon oxide (SiO₂), the capacitive isolation trenches comprise not only an electrically isolating material but also a semiconductor material such as amorphous or polycrystalline silicon. Said trenches can thus be polarized at the desired electrical potential, which allows to improve the performance of the image sensor.

### BRIEF SUMMARY

In various embodiments, a manufacturing method is provided which avoids the formation of a cavity in a capacitive isolation trench.

In at least one embodiment, a method for forming a capacitive isolation trench in a semiconductor substrate, comprising the following successive steps:
digging a trench from a main surface of the substrate, said trench comprising an upper portion gradually widening from a neck in the direction of a lower portion of the trench;
forming a coating of a first electrically isolating material on the walls of the trench;
depositing a first semiconductor material on said coating, said deposition being interrupted so as to leave a free space between the walls of the trench, said free space having an opening at the neck;
depositing a second electrically isolating material in the trench, said deposition resulting in the formation of a plug closing said opening to form a closed cavity;
etching the plug so as to open the cavity;
depositing a second semiconductor material or a metal so as to fill the cavity.

This method has the advantage, thanks to the tight neck formed in the upper part of the trench, of forming a plug located higher in the trench than in the prior art. This plug can then be entirely etched to open the cavity and allow it to be filled after resumption of the deposition of the semiconductor material. Thus, the trench obtained at the end of this method is full and does not contain any cavity capable of accumulating undesirable materials, unlike the trenches of the prior art.

In some embodiments, the lower portion of the trench comprises parallel walls perpendicular to a main surface of the substrate and the upper portion of the trench comprises walls inclined relative to the walls of the lower portion, the width of the upper portion of the trench narrowing from the lower portion of the trench towards the main surface of the substrate.

In some embodiments, the width of the trench at the neck is comprised between 87 and 92% of the width of the lower portion of the trench.

In some embodiments, digging the trench comprises alternating cycles of depositing a protective polymer on the walls of the trench by means of a first gas and of etching the bottom of the trench by means of a second gas, wherein at least one of the following parameters: flow rate of the first gas, deposition time, flow rate of the second gas, etching time, is adjusted to dig the upper portion of the trench with an inclination to form the neck, and at least one of said parameters to dig the lower portion of the trench is modified.

In some embodiments, at least one of the first electrically isolating material and the second electrically isolating material comprises silicon oxide (SiO₂), a high dielectric k, silicon oxynitride (SiON), or silicon nitride (SiN).

In some embodiments, the first semiconductor material comprises amorphous silicon or polycrystalline silicon.

Embodiments of the present disclosure further include a semiconductor substrate comprising a capacitive isolation trench obtained by the method described above.

Said substrate comprises a capacitive isolation trench, said trench successively comprising, from the outside to the inside in a direction parallel to a main surface of the substrate:
an electrically isolating coating,
a first layer of a semiconductor material,
an electrically isolating layer, and
a second layer of the semiconductor material,

said trench comprising an upper portion gradually widening from a neck in the direction of a lower portion of the trench.

In some embodiments, the lower portion of the trench comprises parallel walls perpendicular to the main surface of the substrate and the upper portion of the trench comprises walls inclined relative to the walls of the lower portion, the width of the upper portion of the trench narrowing from the lower portion of the trench towards the main surface of the substrate.

In some embodiments, the width of the trench at the neck is comprised between 87 and 92% of the width of the lower portion of the trench.

Embodiments of the present disclosure further include an image sensor comprising a substrate as described above. At least two pixels of said image sensor are arranged in said substrate and separated by said capacitive isolation trench.

### BRIEF DESCRIPTION OF THE DRAWINGS

Other features and advantages of this method and of the trench obtained by said method will emerge from the detailed description which follows, with reference to the appended drawings wherein:

FIG. 1A is a schematic sectional view of the formation of a photolithography mask on a semiconductor substrate intended in particular for the manufacture of an image sensor;

FIG. 1B is a schematic sectional view of the formation of a trench in the substrate of FIG. 1A through an opening in the mask;

FIG. 1C is a schematic sectional view of the upper region of the substrate surrounding the trench, corresponding to the area surrounded by the dotted frame in FIG. 1B;

FIG. 1D is a schematic sectional view of the partial pull back of the layers covering the substrate on either side of the trench in the region shown in FIG. 1C;

FIG. 1E is a schematic sectional view of the formation of a coating on the walls of the trench in the region shown in FIG. 1D;

FIG. 1F is a schematic sectional view of the formation of an amorphous silicon layer on the coating of FIG. 1E;

FIG. 1G is a schematic sectional view of the filling of the trench of FIG. 1F with silicon oxide;

FIG. 1H is a schematic sectional view of the etching of silicon oxide deposited on the surface of the substrate;

FIG. 1I is a schematic sectional view of the capacitive isolation trench after deposition of a new amorphous silicon layer;

FIG. 2A is a schematic sectional view of the formation of a photolithography mask on a semiconductor substrate intended in particular for the manufacture of an image sensor;

FIG. 2B is a schematic sectional view of the formation of a trench in the substrate of FIG. 1A through an opening in the mask;

FIG. 2C is a schematic sectional view of the upper region of the substrate surrounding the trench, corresponding to the area surrounded by the dotted frame in FIG. 2B;

FIG. 2D is a schematic sectional view of the partial pull back of the layers covering the substrate on either side of the trench in the region shown in FIG. 2C;

FIG. 2E is a schematic sectional view of the formation of a coating on the walls of the trench in the region shown in FIG. 2D;

FIG. 2F is a schematic sectional view of the formation of a first amorphous silicon layer on the coating of FIG. 2E;

FIG. 2G is a schematic sectional view of the filling of the trench of FIG. 2F with silicon oxide;

FIG. 2H is a schematic sectional view of the pull back of the silicon oxide plug formed in the upper part of the trench;

FIG. 2I is a schematic sectional view of the filling of the cavity cleared by the pull back of the plug;

FIG. 2J is a schematic sectional view of the whole of the semiconductor substrate comprising the trench of FIG. 2I.

For reasons of readability of the figures, the drawings are not drawn to scale. Moreover, the drawings were simplified so as to show only the elements useful for the understanding the figures.

In this text, the terms “vertical”, “horizontal”, “lateral”, “lower”, “upper”, “under”, “on”, “above”, “below”, etc. are understood in relation to the orientation of the elements considered in the figures.

Identical reference signs from one figure to another designate an element which is identical or fulfilling the same function. Said element is therefore not necessarily fully described at each new occurrence.

### DETAILED DESCRIPTION

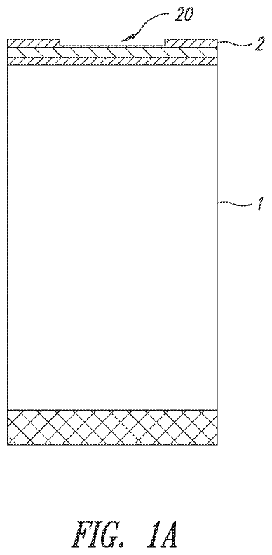

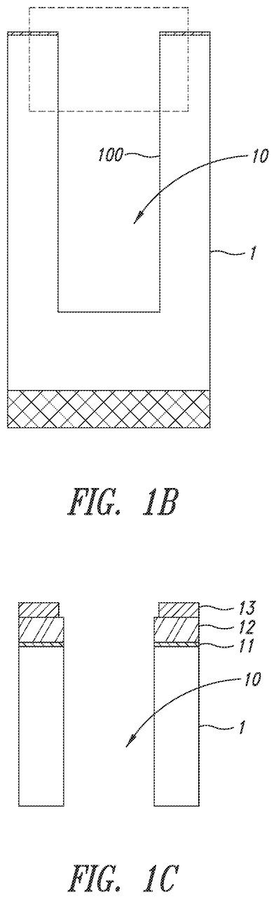

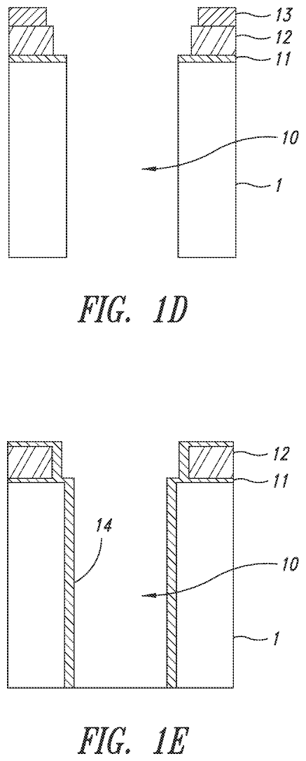

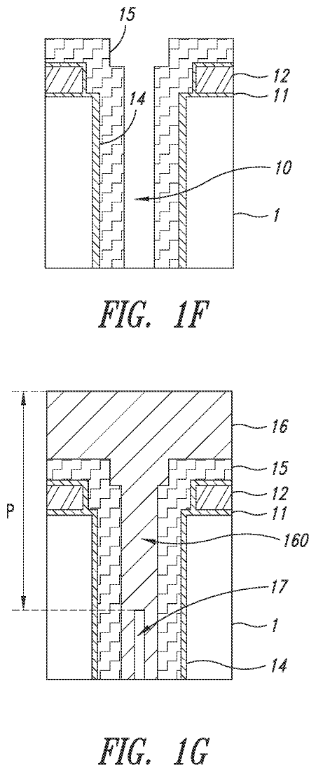

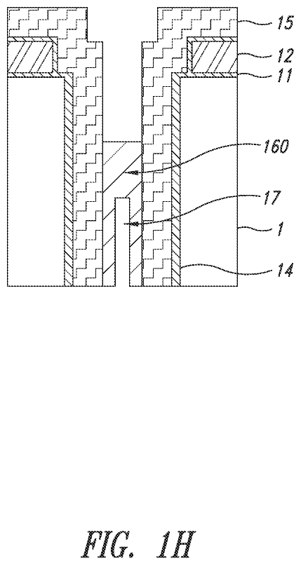

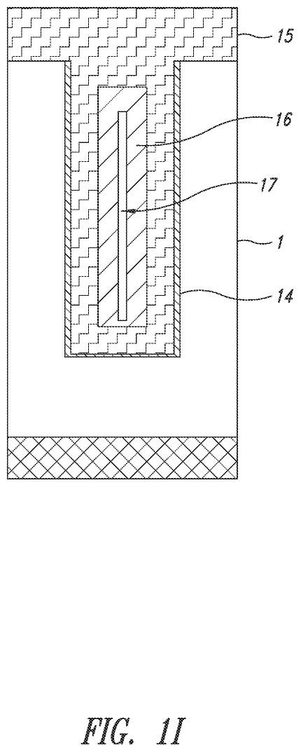

A capacitive isolation trench can be formed according to the method described with reference to FIGS. 1A to 1I.

As illustrated in FIG. 1A, a mask 2 is formed on a semiconductor substrate 1 by photolithography. Said mask comprises at least one opening 20 delimiting, on the surface of the substrate 1, the section of a trench to be formed in said substrate.

With reference to FIGS. 1B and 1C, a trench 10 is formed in the thickness of the substrate 1 from the surface exposed by the opening 20 of the mask.

With reference to FIG. 1D, a partial pull back of the stack of layers which covers the substrate 1 is implemented. Said pull back can be carried out in particular by selective etching of the layers 12 and 13 in a direction parallel to the main surface of the substrate 1, on either side of the trench 10.

With reference to FIG. 1E, a deposition of a silicon oxide (SiO₂) layer 14 is implemented in the trench. This deposition is substantially conformal, so that the layer 14 covers the bottom and the walls of the trench 10.

With reference to FIG. 1F, a deposition of amorphous silicon is implemented in the trench 10. A layer 15 of amorphous silicon is thus formed on the layer 14, which covers the bottom and the walls of the trench 10.

With reference to FIG. 1G, a deposition of silicon oxide is implemented in the trench 10. A silicon oxide layer 16 is thus formed on the layer 15, which covers the bottom and the walls of the trench 10.

This deposition not being conformal, the silicon oxide closes the upper part of the trench before the space comprised between the walls of the trench has been filled in. In other words, this deposition results in the formation of a silicon oxide plug 160 in the upper part of the trench and a cavity 17 under said plug. In FIG. 1G, the cavity is represented in the shape of a continuous volume extending between two parallel walls of the trench, but, depending on the conditions of implementation of the method, the walls of the trenches covered by the amorphous silicon may not be perfectly flat and parallel, so that the cavity 17 may be discontinuous or have a variable section depending on the depth of the trench.

With reference to FIG. 1H, the silicon oxide layer 16 is etched until the amorphous silicon layer 15 is exposed. At the end of this etching, the lower part of the plug 160 remains in the trench. A complete etching of the plug 160 is not achievable because it would considerably increase the duration of the method. In addition, the height of this plug is not controlled; said plug can extend very deep into the trench. Moreover, during this long etching, there would be a significant risk of etching the amorphous silicon deposited beforehand, which would degrade the electrical and optical performance of the image sensor pixels formed in the substrate.

With reference to FIG. 1I, an amorphous silicon deposition is implemented in the upper part of the trench released by the etching of the silicon oxide. Due to the presence of the plug 160, the amorphous silicon does not enter the cavity 17.

Consequently, after the manufacturing method, the cavity 17 remains in the center of the capacitive isolation trench. Such a cavity is problematic insofar as, if the trench is opened during a subsequent step of the manufacturing method of the image sensor, the cavity can open up and is capable of accumulating contaminants or other materials harmful to the performance of the image sensor.

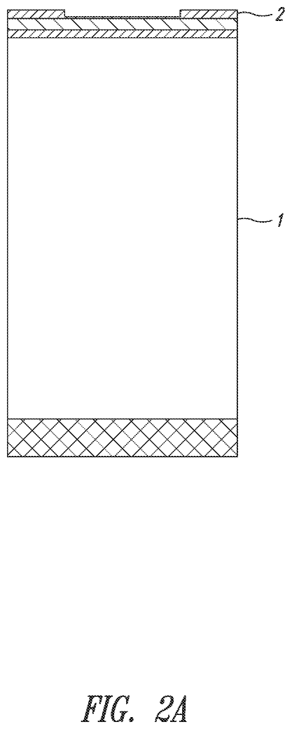

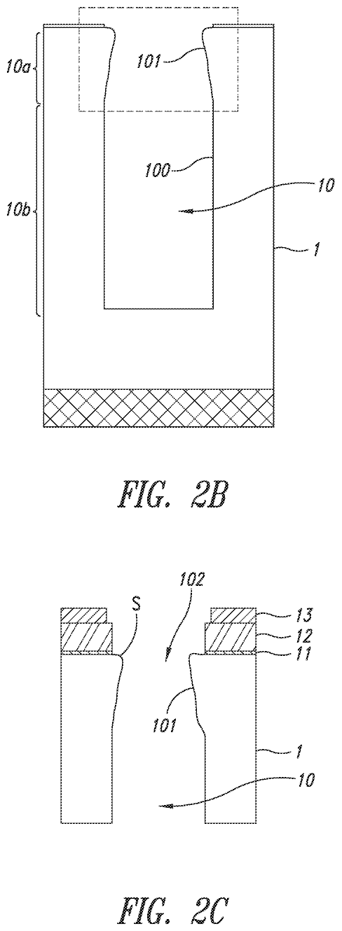

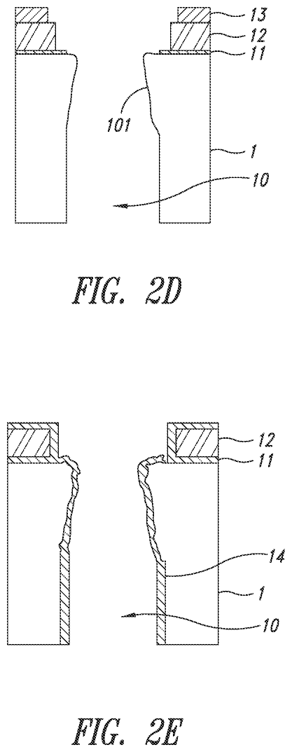

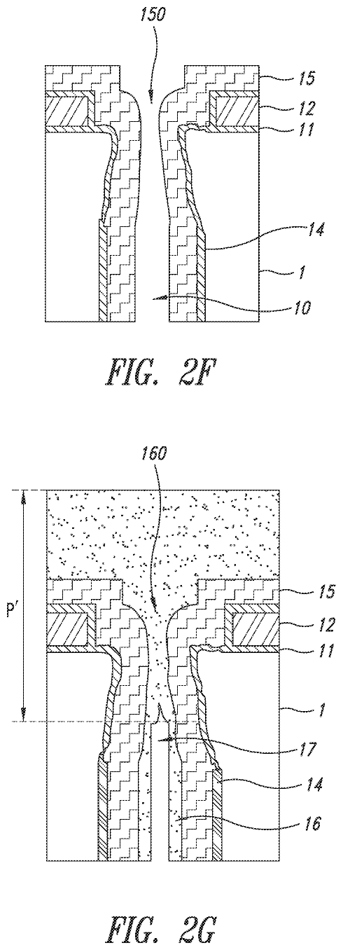

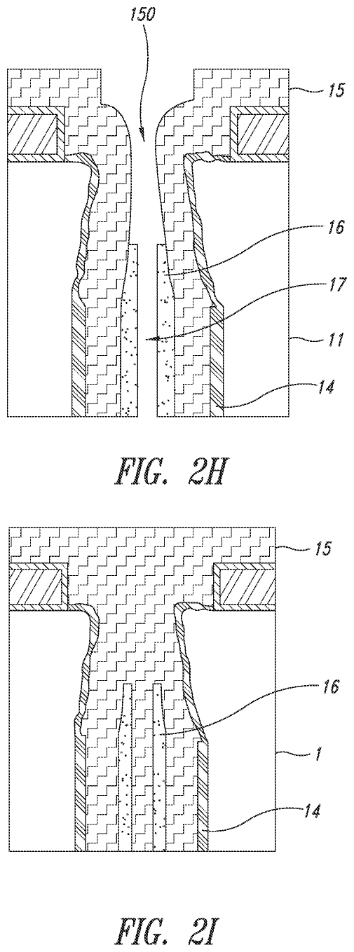

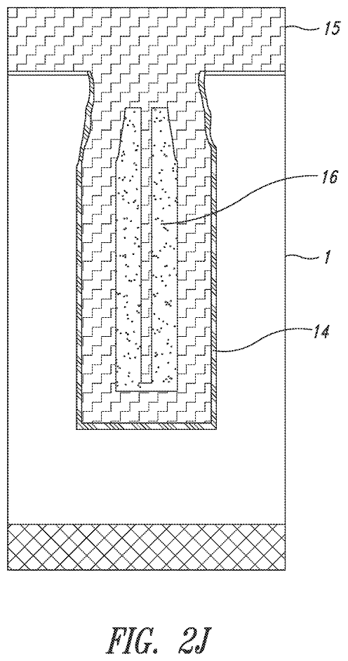

A capacitive isolation trench can be formed according to the method described with reference to FIGS. 2A to 2J.

As illustrated in FIG. 2A, a mask 2 is formed on a semiconductor substrate 1 (which is, for example, a silicon substrate) by photolithography. Said mask comprises at least one opening 20 delimiting, on the surface of the substrate 1, the section of a trench to be formed in said substrate.

As will be better seen in FIG. 2C and the following figures, the semiconductor substrate 1 is successively covered with a silicon oxide layer 11, a silicon nitride (SiN) layer 12 and a silicon oxide layer 13. The layer 13 fulfils a hard mask function for the etching. Said layer 13 protects the SiN layer 12 so that the latter is not etched.

The SiN layer 12 is used as a stop layer for the chemical-mechanical polishing step used to pull back silicon from the surface.

The layer 11 is a thermal oxide layer intended to protect the silicon surface of the substrate 1 when pulling back the SiN layer 12. Said layer 11 also allows to passivate the surface of the substrate 1.

With reference to FIG. 2B, a trench 10 was formed in the thickness of the substrate 1 from the surface exposed by the opening 20 of the mask.

To this end, anisotropic etching of the layers 11, 12, 13 covering the surface of the substrate 1 (which are better visible in FIG. 2C and the following figures) and the substrate 1 itself was implemented, to a sufficient depth for the trench to be formed to provide good electrical isolation of at least two different regions of the substrate 1 from one another.

The trench typically has a width (defined by the distance between the opposite walls in the plane of FIG. 2B) comprised between 150 and 250 nm and a depth of 800 nm to 10 μm. The length of the trench, which is the dimension in a direction perpendicular to the plane of the sheet of FIG. 2B, can vary between a value slightly greater than the width (the trench then being considered as punctual) and a value of several tens of μm (to form an elongated trench).

Unlike the trench of FIG. 1B (whose walls 100 are vertical and whose width is constant), the trench of FIG. 2B has a lower portion 10b whose walls 100 are parallel and vertical and an upper portion 10a whose walls 101 are inclined relative to the walls 100 of the lower portion so as to cause a narrowing of the trench from the bottom to the top of said upper portion (or, conversely, a widening of the trench from the top to the bottom of the upper portion). The lower portion 10b of the trench, on the other hand, has a constant width.

In other words, the trench 10 has, at the upper surface S of the substrate 1, a neck 102 of smaller width than the rest of the trench. The extension of the neck in the horizontal direction relative to the wall of the lower portion of the trench may be of the order of 10 nm on each side, which represents a narrowing of 20 nm from the average width of the trench. Considering a width of the trench comprised between 150 and 250 nm, the neck represents a restriction of 8% to 13% of the width of the trench. In other words, the ratio between the minimum width of the trench (at the neck) and the maximum width of the trench (at the lower portion) is comprised between 87% and 92%.

This neck can be obtained by adjusting the operating conditions for digging the trench in order to promote the formation of the neck then to protect the neck thus formed when the etching of the trench is continued.

Digging the trench is carried out gradually in the direction of the depth of the substrate. It involves a rapid alternation of steps of depositing polymers intended to protect the walls of the trench and etching the bottom of the trench.

The polymer is deposited by means of a gas, for example, perfluorocyclobutane (C₄F₈) sprayed into the trench so as to cover the walls of the trench.

The etching is carried out using another gas, for example, sulphur hexafluoride (SF₆). Given the direction of the gas flow, the etching takes place mainly at the bottom of the trench; moreover, the walls of the trench being protected by the deposited polymer, the lateral etching is minimized.

The deposition and etching steps can be controlled mainly by their duration and by the gas flow rate to adjust the thickness of the deposited polymer and/or the amount of etched material; the duration and the gas flow rate can also vary during the digging depending on the depth reached in the substrate. Each deposition and etching step typically lasts a few hundredths of a second, for example, between 0.1 and 0.3 s. Moreover, the flow rate of the deposition gas can typically vary during the digging of the trench, between 25 and 100 cm³/min, and the flow rate of the etching gas can vary between 10 and 150 cm³/min.

To create the neck and laterally etch the substrate to form the inclined wall in the upper portion of the trench, it is possible, for example, to adjust the duration and/or the polymer deposition rate to deposit a relatively large thickness of polymer at the start of the digging of the trench, so as to promote a slope etching to form the neck, then reduce the duration and/or the polymer deposition rate to reduce the thickness of deposited polymer, so as to promote vertical etching of the walls of the trench under the neck. As the trench is dug, the duration of the deposition and etching steps may increase. The person skilled in the art is able to determine the appropriate deposition and etching parameters, in particular by means of simulations.

With reference to FIG. 2D, a partial pull back of the stack of layers 11, 12, 13 which covers the substrate 1 was implemented. This pull back is intended to widen the upper part of the trench to allow better filling of the trench with an electrically isolating material in the next step. Said pull back can be achieved in particular by selective etching of the layers 12 and 13 in a direction parallel to the main surface of the substrate 1, on either side of the trench 10. At the end of this pull back step, the layer 13 was completely pulled back from the surface of the substrate.

With reference to FIG. 2E, a deposition of a layer 14 of an electrically isolating material, such as silicon oxide (SiO₂), a “high k” dielectric (for example, HFO₂, Ta₂O₅, Al₂O₃ or ZrO₂) or silicon oxynitride (SiON), was implemented in the trench. This deposition is substantially conformal, so that the layer 14 covers the bottom and the walls of the trench 10. The coating 14 fulfils the function of dielectric in the capacitor formed by the trench, said coating 14 separating the electrodes of said capacitor which are formed, on the one hand, by the semiconductor material of the substrate 1, and on the other hand, by a semiconductor material deposited on the coating 14 in the following step.

With reference to FIG. 2F, a deposition of a first semiconductor material, such as amorphous silicon or polycrystalline silicon, was implemented in the trench 10. Thus, a layer 15 of amorphous silicon was formed on the layer 14, which covers the bottom and the walls of the trench 10. The deposition was stopped so as to leave, at the neck of the trench, an opening 150 which opens onto a free space between the amorphous silicon layers extending over the opposite walls of the trench. The width of this opening 150 is generally of the order of 80 to 120 nm.

With reference to FIG. 2G, a deposition of a second electrically isolating material, such as silicon oxide or silicon nitride, was implemented in trench 10. Thus, a layer 16 of silicon oxide or nitride was formed on the layer 15, which covers the bottom and the walls of the trench 10 and which closes the opening 150. As in the method of the prior art, a cavity 17 extending into the trench under the opening 150 blocked by silicon oxide or nitride remains at the end of this step.

However, this cavity can then be filled in during the steps set out below.

With reference to FIG. 2H, the upper part of the layer 16 was etched so as to pull back the silicon oxide or nitride plug 160 formed in the opening 150. This etching allows to make the cavity 17 open towards the upper surface of the substrate 1 through the opening.

With reference to FIG. 2I, a second deposition of amorphous or polycrystalline silicon was implemented in the trench. As better seen in FIG. 2J, the cavity 17 was thus completely filled in to the upper surface of the substrate 1. The material used in the second deposition is not necessarily identical to the material of the first deposition. For example, instead of a semiconductor material such as amorphous or polycrystalline silicon, the material of the second deposition can be an electrically conductive material such as a metal.

The depositions implemented in the method can be produced by Chemical Vapor Deposition (CVD).

As seen in FIG. 2J, the trench has, from the outside to the inside in a direction parallel to the surface of the substrate, the electrically isolating coating 14, a first layer of semiconductor material 15, an electrically isolating layer 16 and a second layer of semiconductor material 15, which is located at the center of the trench.

A capacitive isolation trench was thus formed which, unlike the trenches of the prior art, does not contain a cavity. Such a trench is therefore not subject to the risk of accumulation of undesirable materials.

This filling of the cavity is made possible in particular by the neck formed in the upper part of the trench. Indeed, thanks to this neck, the depth of the silicon oxide plug extending in the upper part of the trench from the upper surface of the silicon oxide layer 16, designated by the mark P′ in FIG. 2G, is substantially less than the depth of the plug in the case of a straight-walled trench according to the prior art, designated by the mark P in FIG. 1G. It is thus possible, during the etching of the plug, to completely pull back said plug and make the cavity 17 open upwards, which then allows to fill in said cavity during the second deposition of amorphous silicon.

The capacitive isolation trench can advantageously be used in a rear-illuminated image sensor, to electrically isolate two adjacent pixels and provide active passivation.

However, any other application can be considered. Thus, for example, the capacitive isolation trench can be used advantageously in power electronics. In this type of application, the dimensions of the trenches are larger. In particular, the trenches are wider (of the order of a few micrometers, for example, of the order of 2 μm) and deeper (of the order of a few tens of micrometers, for example, of the order of 27 μm). The electric current supported by this architecture can be several hundred volts (compared to a few volts for image sensors). According to the same principle as described above, the trench is formed with a neck in its upper portion, with the same order of magnitude of the ratio between the minimum width of the trench (at the neck) and the maximum width of the trench of the order of 90%. The steps of forming the trench are similar to those described above, with adaptations in terms of the number of polymer deposition/etching cycles and the thickness of the deposited materials related to the dimensions of the trench. Thus, for example, the electrically isolating coating 14 is much thicker than in the previous application (between 500 and 1000 nm). The person skilled in the art is able to adjust the operating conditions of the method according to these dimensions.

A method for forming a capacitive isolation trench in a semiconductor substrate, may be summarized as including the following successive steps: digging a trench (10) from a main surface of the substrate (1), said trench including an upper portion (10a) gradually widening from a neck (102) in the direction of a lower portion (10b) of the trench; forming a coating of a first electrically isolating material (14) on the walls of the trench; depositing a first semiconductor material (15) on said coating, said deposition being interrupted so as to leave a free space between the walls (100, 101) of the trench, said free space having an opening (150) at the neck (102); depositing a second electrically isolating material (16) in the trench, said deposition resulting in the formation of a plug (160) closing said opening (150) to form a closed cavity (17); etching the plug (16) so as to open the cavity (17); depositing a second semiconductor material or a metal so as to fill the cavity (17).

The lower portion (10b) of the trench may include parallel walls (100) perpendicular to a main surface (S) of the substrate and the upper portion (10a) of the trench includes walls (101) inclined relative to the walls (100) of the lower portion, the width of the upper portion (10a) of the trench narrowing from the lower portion (10b) of the trench towards the main surface (S) of the substrate.

The width of the trench at the neck (102) may be included between 87 and 92% of the width of the lower portion (10b) of the trench.

Digging the trench (10) may include alternating cycles of depositing a protective polymer on the walls of the trench by means of a first gas and of etching the bottom of the trench by means of a second gas, and wherein at least one of the following parameters: flow rate of the first gas, deposition time, flow rate of the second gas, etching time, is adjusted to dig the upper portion of the trench with an inclination to form the neck, and at least one of said parameters to dig the lower portion of the trench is modified.

At least one of the first electrically isolating material (14) and the second electrically isolating material (16) may include silicon oxide (SiO₂), a high dielectric k, silicon oxynitride (SiON), or silicon nitride (SiN).

The first semiconductor material (15) may include amorphous silicon or polycrystalline silicon.

A semiconductor substrate may be summarized as including a capacitive isolation trench, said trench successively including, from the outside to the inside in a direction parallel to a main surface (S) of the substrate: an electrically isolating coating (14), a first layer of a semiconductor material (15), an electrically isolating layer (16), and a second layer of the semiconductor material (15), said trench including an upper portion (10a) gradually widening from a neck (102) in the direction of a lower portion (10b) of the trench.

The lower portion (10b) of the trench may include parallel walls (100) perpendicular to the main surface (S) of the substrate and the upper portion (10a) of the trench includes walls (101) inclined relative to the walls (100) of the lower portion, the width of the upper portion (10a) of the trench narrowing from the lower portion (10b) of the trench towards the main surface (S) of the substrate.

The width of the trench at the neck (102) may be included between 87 and 92% of the width of the lower portion (10b) of the trench.

An image sensor may be summarized as including a substrate, wherein at least two pixels of said image sensor are arranged in said substrate and separated by said capacitive isolation trench.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a trench extending into a semiconductor substrate from a first surface of the substrate, the trench including an upper portion gradually widening from a neck in the direction of a lower portion of the trench;
forming a coating of a first electrically isolating material on walls of the trench;
forming a first semiconductor material on the coating, the first semiconductor material at least partially defining a free space between the walls of the trench, said free space having an opening at the neck;
forming a second electrically isolating material in the trench, the second electrically isolating material defining a plug that closes said opening to form a closed cavity;
opening the cavity by removing portions of the plug; and
filling the cavity with a second semiconductor material or a metal.

2. The method according to claim 1, wherein the lower portion of the trench includes parallel walls perpendicular to the first surface of the substrate and the upper portion of the trench includes walls inclined relative to the walls of the lower portion, a width of the upper portion of the trench narrowing from the lower portion of the trench towards the first surface of the substrate.

3. The method according to claim 1, wherein the width of the trench at the neck is between 87% and 92% of the width of the lower portion of the trench.

4. The method according to claim 1, wherein forming the trench comprises alternating cycles of depositing a protective polymer on the walls of the trench by a first gas and etching the bottom of the trench by a second gas.

5. The method according to claim 4, wherein at least one of the following parameters: flow rate of the first gas, deposition time, flow rate of the second gas, etching time, is adjusted to form the upper portion of the trench with an inclination to form the neck, and at least one of said parameters is modified to form the lower portion of the trench.

6. The method according to claim 1, wherein at least one of the first electrically isolating material or the second electrically isolating material includes silicon oxide (SiO₂), a high dielectric k, silicon oxynitride (SiON), or silicon nitride (SiN).

7. The method according to claim 1, wherein the first semiconductor material includes amorphous silicon or polycrystalline silicon.

8. The method according to claim 1, wherein forming the trench includes digging the trench from the first surface of the substrate.

9. The method according to claim 1, wherein forming the first semiconductor material on the coating includes depositing the first semiconductor material on the coating, and forming the second electrically isolating material in the trench includes depositing the second electrically isolating material in the trench.

10. The method according to claim 1, wherein removing portions of the plug includes removing portions of the plug by etching.

11. The method according to claim 1, wherein filling the cavity with the second semiconductor material or the metal includes depositing the second semiconductor material or the metal.

12. A device, comprising:
a semiconductor substrate; and
a capacitive isolation trench including:
a trench extending into the semiconductor substrate from a first surface, the trench having an upper portion gradually widening from a neck of the trench toward a lower portion of the trench;
an electrically isolating coating on walls of the trench;
a first layer of a semiconductor material on the coating;
an electrically isolating layer on the first layer of the semiconductor material; and
a second layer of the semiconductor material on the electrically isolating layer, the electrically isolating layer disposed between the first and second layers of the semiconductor material.

13. The device according to claim 12, wherein the lower portion of the trench includes parallel walls perpendicular to the first surface of the substrate and the upper portion of the trench includes walls inclined relative to the walls of the lower portion, a width of the upper portion of the trench narrowing from the lower portion of the trench towards the first surface of the substrate.

14. The device according to claim 12, wherein the width of the trench at the neck is between 87% and 92% of the width of the lower portion of the trench.

15. The device according to claim 12, wherein at least one of the electrically isolating coating or the electrically isolating layer includes silicon oxide (SiO₂), a high dielectric k, silicon oxynitride (SiON), or silicon nitride (SiN).

16. The device according to claim 12, wherein the semiconductor material includes amorphous silicon or polycrystalline silicon.

17. An image sensor, comprising:
a semiconductor substrate;
a capacitive isolation trench including:
a trench extending into the semiconductor substrate from a first surface, the trench having an upper portion gradually widening from a neck of the trench toward a lower portion of the trench;
an electrically isolating coating on walls of the trench;
a first layer of a semiconductor material on the coating;
an electrically isolating layer on the first layer of the semiconductor material; and
a second layer of the semiconductor material on the electrically isolating layer, the electrically isolating layer disposed between the first and second layers of the semiconductor material; and
a plurality of pixels, wherein at least two pixels of the plurality of pixels are arranged in said substrate and separated by the capacitive isolation trench.

18. The image sensor according to claim 17, wherein the lower portion of the trench includes parallel walls perpendicular to the first surface of the substrate and the upper portion of the trench includes walls inclined relative to the walls of the lower portion, a width of the upper portion of the trench narrowing from the lower portion of the trench towards the first surface of the substrate.

19. The image sensor according to claim 17, wherein the width of the trench at the neck is between 87% and 92% of the width of the lower portion of the trench.

20. The image sensor according to claim 17, wherein at least one of the electrically isolating coating or the electrically isolating layer includes silicon oxide (SiO₂), a high dielectric k, silicon oxynitride (SiON), or silicon nitride (SiN).
